(19) United States
(12) Patent Application Publication
(10) Pub. No.: US 2015/0069510 A1
(43) Pub. Date: Mar. 12, 2015

(54) THIN FILM TRANSISTOR, ARRAY SUBSTRATE, AND DISPLAY PANEL

(71) Applicant: SHENZHEN CHINA STAR OPTOELECTRONICS TECHNOLOGY CO., LTD., Shenzhen, Guangdong (CN)

(72) Inventors: Peng Du, Shenzhen City (CN); Cheng-hung Chen, Shenzhen City (CN)

(73) Assignee: SHENZHEN CHINA STAR OPTOELECTRONICS TECHNOLOGY CO., LTD., Shenzhen, Guangdong (CN)

(21) Appl. No.: 14/233,386

(22) PCT Filed: Oct. 24, 2013
(86) PCT No.: PCT/CN2013/085838

§ 371 Date: Jan. 17, 2014

(30) Foreign Application Priority Data
Sep. 10, 2013 (CN) 2013104111314

(51) Int. Cl. H01L 29/786; H01L 27/12

(52) U.S. Cl. CPC H01L 29/786; H01L 27/1214
USPC 257/347

(57) ABSTRACT

A TFT, an array substrate, and a display panel are disclosed. The TFTs includes a gate, a first insulation layer arranged above the (late, a second insulation layer arranged above the first insulation layer, a semiconductor layer, a source, and a drain arranged between the first insulation layer and the second insulation layer, and a conductive layer arranged above the second insulation layer. The conductive layer and the gate are electrically coupled to each other such that when the TFT is in a turn-on state. A turn-on current generated in conductive channels of the semiconductor layer is increased. When the TFT is in a turn-off state, a turn-off current generated in the conductive channels is decreased. In this way, the ratio of the turn-on current to the turn-off current is increased.

### BACKGROUND OF THE INVENTION

1. Field of the Invention

The present disclosure relates to display technology, and more particularly to a thin film transistor (TFT), an array substrate and a display panel.

2. Discussion of the Related Art

TFTs, which operate as switching components for display panels, are semiconductor devices utilizing the current between a gate, a source, and a drain. The TFT includes the gate, an insulation layer, a semiconductor layer, and the source and the drain arranged turn. Electrons are carriers for providing conductive functions in the TFT conductive channels.

The operating principle of the TFT is described hereinafter. When the gate increases the voltage, the electrons couple in the proximity of the gate. The electron concentration increases so as to form a pre-conductive channel between the source and the drain. The pre-conductive channel is below the source and the drain. During operations, the current between the source and the drain has to pass through the semiconductor layer so as to arrive the pre-conductive channel. The resistance of the semiconductor layer is larger. In an off-state, a back channel accumulating the electrons is formed in the proximity of the source and the drain such that leakage current occurs, which results in the increasing current when the TFT is in the off-state and the Ion/IOff ratio is decreased.

### SUMMARY

The object of the invention is to provide a TFT, an array substrate and a display panel. In the on-state, the resistance of the conductive channel is decreased and the switching current is increased. In the off-state, the electron concentration of the conductive channel is decreased and the turn-off current is decreased so as to increase the Ion/Ioff ratio.

In one aspect, a thin film transistor (TFT) includes: a gate; a first insulation layer arranged above the gate; a second insulation layer arranged above the first insulation layer; a semiconductor layer, a source, and a drain arranged between the first insulation layer and the second insulation layer; and a conductive layer arranged above the second insulation layer, the conductive layer and the gate are electrically coupled to each other such that when the TFT is in a turn-on state, a turn-on current generated in conductive channels of the semiconductor layer is increased, and when the TFT is in a turn-off state, a turn-off current generated in the conductive channels of the semiconductor layer is decreased.

Wherein a first opening is arranged above the gate, the first opening passes through the first insulation layer and the second insulation layer to expose the gate, and the conductive layer connects to the gate via the first opening.

Wherein the conductive layer is an Indium Tin Oxide (ITO) film or a metallic layer.

Wherein the semiconductor layer is arranged above the first insulation layer, the source and the drain are arranged above the semiconductor layer, the TFT further includes an ohm-contact layer arranged between the semiconductor layer, the source and the drain, the ohm-contact layer includes a second opening passing through the ohm-contact layer via a gap between the source and the drain to expose the semiconductor layer, and the second insulation layer connects to the semiconductor layer is the second opening.

Wherein the source and the drain are arranged. above the first insulation layer, the semiconductor layer is arranged above the source and the drain, the TFT further includes an ohm-contact layer being arranged between the semiconductor layer, the source and the drain, the ohm-contact layer includes a second opening passing through the ohm-contact layer via a gap between the source and the drain to expose the first insulation layer, and the semiconductor layer connects to the first insulation layer via the second opening.

In another aspect, an array substrate includes: a substrate and a plurality of TFTs arranged on the substrate, the TFT includes: a gate; a first insulation layer arranged above the gate; a second insulation layer arranged above the first insulation layer; a semiconductor layer, a source, and a drain arranged between the first insulation layer and the second insulation layer; and a conductive layer arranged above the second insulation layer, the conductive layer and the gate are electrically coupled to each other such that when the TFT is in a turn-on state, a turn-on current generated in conductive channels of the semiconductor layer is increased, and when the TFT is in a turn-off state, a turn-off current generated in the conductive channels of the semiconductor layer is decreased.

Wherein a first opening is arranged above the gate, the first opening passes through the first insulation layer and the second insulation layer to expose the gate, and the conductive layer connects to the gate via the first opening.

Wherein the conductive layer is an ITO film or a metallic layer.

Wherein the semiconductor layer is arranged above the first insulation layer, the source and the drain are arranged above the semiconductor layer, the TFT further includes an ohm-contact layer arranged between the semiconductor layer, the source and the drain, the ohm-contact layer includes a second opening passing through the ohm-contact layer via a gap between the source and the drain to expose the semiconductor layer, and the second insulation layer connects to the semiconductor layer via the second opening.

Wherein the source and the drain are arranged above the first insulation layer, the semiconductor layer is arranged above the source and the drain, the TFT further includes an ohm-contact layer being arranged between the semiconductor layer, the source and the drain, the ohm-contact layer includes a second opening passing through the ohm-contact layer via a gap between the source and the drain to expose the first insulation layer, and the semiconductor layer connects to the first insulation layer via the second opening.

In another aspect, a display panel includes: an array substrate and a color-film substrate arranged opposite to the array substrate, the array substrate includes a substrate and a plurality of TFTs arranged on the substrate, the TFT includes: a gate;

a first insulation layer arranged above the gate, a second insulation layer arranged above the first insulation layer; a semiconductor layer, a source, and a drain arranged between the first insulation layer and the second insulation layer; and a conductive layer arranged above the second insulation layer, the conductive layer and the gate are electrically coupled to each other such that when the TFT is in a turn-on state, a turn-on current generated in conductive channels of the semiconductor layer is increased, and when the TFT is in a turn-off state, a turn-off current generated in the conductive channels of the semiconductor layer is decreased.

Wherein a first opening is arranged above the gate, the first opening passes through the first insulation layer and the second insulation layer to expose the gate, and the conductive layer connects to the gate via the first opening.

Wherein the conductive layer is an ITO film or a metallic layer.

Wherein the semiconductor layer is arranged above the first insulation layer, the source and the drain are arranged above the semiconductor layer, the TFT further includes an ohm-contact layer arranged between the semiconductor layer, the source and the drain, the ohm-contact layer includes a second opening passing through the ohm-contact layer via a gap between the source and the drain to expose the semiconductor layer, and the second insulation layer connects to the semiconductor layer via the second opening.

Wherein the source and the drain are arranged above the first insulation layer, the semiconductor layer is arranged above the source and the drain, the TFT further includes an ohm-contact layer being arranged between the semiconductor layer, the source and the drain, the ohm-contact layer includes a second opening passing through the ohm-contact layer via a gap between the source and the drain to expose the first insulation layer, and the semiconductor layer connects to the first insulation layer via the second opening.

In view of the above, the TFT includes the gate, the first insulation layer, the semiconductor layer, the source, the drain, the second insulation layer, and the conductive layer. The first insulation layer is arranged above the gate. The second insulation layer is arranged above the first insulation layer. The semiconductor, the source and the drain are arranged between the first insulation layer and the second insulation layer. The conductive layer is arranged above the second insulation layer so as to be electrically coupled to the gate. With the above configuration, the gate and the conductive layer receive the turn-on signals and the turn-off signals at the same. The gate and the conductive layer respectively form two conductive channels in the semiconductor layer upon receiving the turn-on signals. The resistance of the conductive channels is reduced such that the turn-on current is increased. The gate and the conductive layer simultaneously reject the electrons in the conductive channel upon receiving the turn-off signals to decrease the turn-off current, i.e., reduce current leakage. As such, the Ion/Ioff ratio is enhanced.

### BRIEF DESCRIPTION OF THE DRAWINGS

FIG. 1 is a schematic view of the TFT in accordance with one embodiment.

FIG. 2 is a schematic view of the TFT of FIG. 1 in the turn-on state.

FIG. 3 is a schematic view of the TFT of FIG. 1 in the turn-off state.

FIG. 4 is a schematic view of the TFT in accordance with another embodiment.

FIG. 5 is a schematic view of the array substrate in accordance with one embodiment.

FIG. 6 is a schematic view of the display panel in accordance with one embodiment

### DETAILED DESCRIPTION OF THE EMBODIMENTS

Embodiments of the invention will now be described, more fully hereinafter with reference to the accompanying drawings, in which embodiments of the invention are shown.

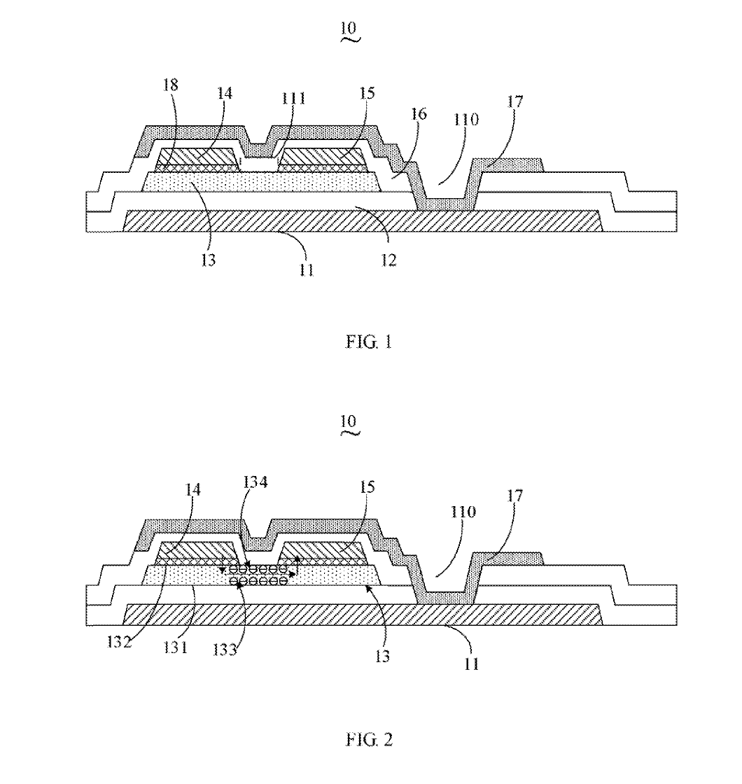

FIG. 1 is a schematic view of the TFT in accordance with one embodiment. As shown in FIG. 1, the TFT 10 includes a gate 11, a first insulation layer 12, a semiconductor layer 13, a source 14, a drain 15, a second insulation layer 16, and a conductive layer 17. The first insulation layer 12 is arranged above the gate 11. The second insulation layer 16 is arranged above the first insulation layer 12, The semiconductor layer 13, the source 14, and the drain 15 are arranged between the first insulation layer 12 and the second insulation layer 16. The conductive layer 17 is arranged above the second insulation layer 16, and the conductive layer 17 and the gate 11 are electrically coupled to each other. In this way, when the TFT 10 is in the turn-on state, the turn-on current generated in the conductive channel of the semiconductor layer 13 is increased. When the TFT 10 is in the turn-off state, the turn-off current in the conductive channel of the semiconductor layer 13 is decreased.

In one embodiment, a first opening 110 is arranged above the gate 11. The first opening 110 passes through the first insulation layer 12 and the second insulation layer 16 to expose the gate 11. The conductive layer 17 connects with the gate 11 via the first opening 110. The conductive layer 17 may be an Indium Tin Oxide (ITO) film or a metallic layer. The conductive layer 17 may be other conductive materials only if the gate 11 and the conductive layer 17 are electrically coupled to each other.

In one embodiment the semiconductor layer 13 is arranged above the first insulation layer 12. The source 14 and the drain 15 are arranged above the semiconductor layer 13. In addition, the source 14 and the drain 15 are arranged at two lateral sides of the semiconductor layer 13. The TFT 10 further includes an ohm-contact layer 18 arranged between the semiconductor layer 13 and the source 14, the drain 15. In addition, the ohm-contact layer 18 includes a second opening 111 passing, through the ohm-contact layer 18 via a imp between the source 14 and the drain 15 to expose the semiconductor layer 13. The second insulation layer 16 connects to the semiconductor layer 13 via the second opening 111.

The operating principles of the TFT 10 will be described hereinafter.

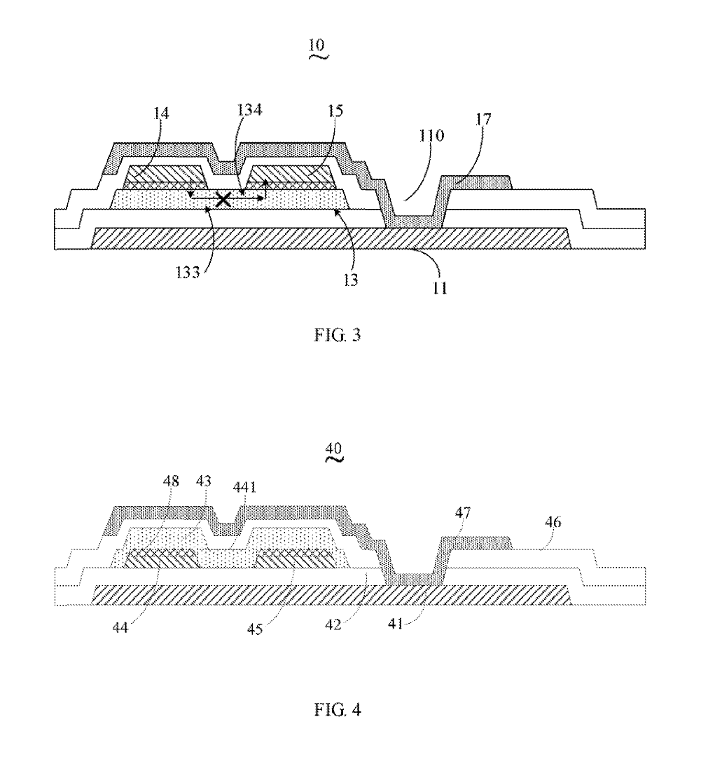

FIG. 2 is a schematic view of the TFT of FIG. 1 in the turn-on state. FIG. 3 is a schematic view of the TFT of FIG. 1 in the turn-off state. As show in FIG. 2, the TFT 10 is in the turn-on state when the gate 11 of the TFT 10 receives the turn-on signals, high voltage. The source 14 and the drain 15 are electrically connected via the semiconductor layer 13. The electrons are carriers for activation the conduction function. In one embodiment, as the conductive layer 17 and the gate 11 are connected via the first opening 110, the gate 11 and the conductive layer 17 receive the turn-on signals at the same time. At this moment, the conductive channels 133, 134 are respectively formed at one side 131 of the semiconductor layer 13 close to the gate 11 and another side 132 of the semiconductor layer 13 close to the conductive layer 17. The current between the source 14 and the drain 15 are transferred via conductive channels 133, 134.

As shown in FIG. 3, the TFT 10 is in the turn-off state when the gate 11 of the TFT 10 receives the turn-off signals. At this moment, the source 14 and the drain 15 are electrically insulated. Specifically, the conductive layer 17 receives the turn-off signals at the same time At this moment, the electrons formed in the conductive channels 133, 134 are rejected by the gate 11 and the conductive layer 17 such that no current is transferred between the source 14 and the drain 15.

In view of the above, two conductive channels 133, 134 are formed when the TFT 10 is in the turn-on state. The resistance of the conductive channels is reduced such that the turn-on current is increased. When in the turn-off state, the electrons in the conductive channels 133, 134 are rejected by the gate 11 and the conductive layer 17. The turn-off current is decreased. That is, the current leakage is also decreased. In this way, the ratio of the turn-on current to the turn-off current is increased.

FIG. 4 is a schematic view of the TFT in accordance with another embodiment. As shown in FIG. 4, the TFT 40 includes the gate 41, the first insulation layer 42, the semiconductor layer 43, the source 44, the drain 45, the second insulation layer 46, the conductive layer 47, and the ohm-contact layer 48. The difference between the TFT 40 and the TFT 10 of FIG. 1 will be described hereinafter. The source 44 and the drain 45 are arranged above the first insulation layer 42. The semiconductor layer 43 is arranged above the source 44 and the drain 45. The ohm-contact layer 48 is arranged between the semiconductor layer 43 and the source 44, drain 45. In addition, the ohm-contact layer 48 includes the second opening 441 passing through the ohm-contact layer 48 via the gap between the source 44 and the drain 45 to expose the first insulation layer 42. The semiconductor layer 43 connects to the first insulation layer 42 via the second opening 441.

The operating principle of the IFT 40 is substantially the same with that of the TFT 10 of the first embodiment.

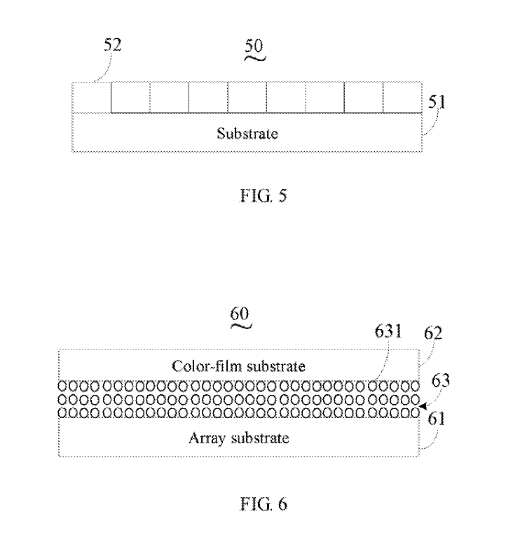

FIG. 5 is a schematic view of the array substrate in accordance with one embodiment. As shown in FIG. 5, the array substrate 50 includes a substrate 51 and a plurality of TFTs 52 arranged on the substrate 51. The TFTs 52 may be the above-mentioned TFT 10 or TFT 40.

FIG. 6 is a schematic view of the display panel in accordance with one embodiment. As shown in FIG. 6, the display panel 60 includes an array substrate 61 and a color-film substrate 62 arranged opposite to the array substrate 61, and a liquid crystal layer 63 between the array substrate 61 and the color-film substrate 62. The array substrate 61 and the color-film substrate 62 cooperatively control the alignment of the liquid crystal 631 within the liquid crystal layer 63 to control the light beams passing through the liquid crystal layer 63 so as to obtain needed images. In the embodiment, the array substrate 61 is the above-mentioned array substrate 50.

In view of the above, by adding one conductive layer above the second insulation layer, two conductive, channels are formed when the TFT is in the turn-on state. The resistance of the conductive channels is reduced such that the turn-on current is increased. When in the turn-off state, the electrons in the conductive, channels are rejected by the gate and the conductive layer. The turn-off current is decreased. That is, the current leakage is also decreased. In this way, the ratio of the turn-on current to the turn-off current is increased.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A thin film transistor (TFT), comprising:
a gate,
a first insulation layer arranged above the gate;
a second insulation layer arranged above the first insulation layer;
a semiconductor layer, a source, and a draw arranged between the first insulation layer and the second insulation layer; and
a conductive layer arranged above the second insulation layer, the conductive layer and the gate are electrically coupled to each other such that when the TFT is in a turn-on state, a turn-on current generated in conductive channels of the semiconductor layer is increased, and when the TFT is in a turn-off state, a turn-off current generated in the conductive channels of the semiconductor layer is decreased.

2. The TFT as claimed in claim 1, wherein a first opening is arranged above the gate, the first opening passes through the first insulation layer and the second insulation layer to expose the gate, and the conductive layer Connects to the gate via the first opening.

3. The TFT as claimed in claim 1, wherein the conductive layer is an indium Tin Oxide (ITO) film or a metallic layer.

4. The TFT as claimed in claim 1, wherein the semiconductor layer is arranged above the first insulation layer, the source and the drain are arranged above the semiconductor layer, the TFT further comprises an ohm-contact layer arranged between the semiconductor layer, the source and the drain, the ohm-contact layer comprises a second opening passing through the ohm-contact layer via a gap between the source and the drain to expose the semiconductor layer, and the second insulation layer connects to the semiconductor layer via the second opening.

5. The TFT as claimed in claim 1, wherein the source and the drain are arranged above the first insulation layer, the semiconductor layer is arranged above the source and the drain, the TFT further comprises an ohm-contact layer being arranged between the semiconductor layer, the source and the drain, the ohm-contact layer comprises a second opening passing through the ohm-contact layer via a gap between the source and the drain to expose the first insulation layer, and the semiconductor layer connects to the first insulation layer via the second opening.

6. An array substrate, comprising:
a substrate and a plurality of TFTs arranged on the substrate, the TFT comprises:
a gate;
a first insulation layer arranged above the gate;
a second insulation layer arranged above the first insulation layer;
a semiconductor layer, a source, and a drain arranged between the first insulation layer and the second insulation layer; and
a conductive layer arranged above the second insulation layer, the conductive layer and the gate are electrically coupled to each other such that when the TFT is in a turn-on state, a turn-on current generated in conductive channels of the semiconductor layer is increased, and when the TFT is in a turn-off state, a turn-off current generated in the conductive channels of the semiconductor layer is decreased.

7. The array substrate as claimed in claim 6, wherein a first opening is arranged above the gate, the first opening passes through the first insulation layer and the second insulation layer to expose the gate, and the conductive layer connects to the gate via the first opening.

8. The array substrate as claimed in claim 6, wherein the conductive layer is an ITO film or a metallic layer.

9. The array substrate as claimed in claim 6, wherein the semiconductor layer is arranged above the first insulation layer, the source and the drain are arranged above the semiconductor layer, the TFT further comprises an ohm-contact layer arranged between the semiconductor layer, the source and the drain, the ohm-contact layer comprises a second opening passing through the ohm-contact layer via a gap between the source and the drain to expose the semiconductor layer, and the second insulation layer connects to the semiconductor layer via the second opening.

10. The array substrate as claimed in claim 6, wherein the source and the drain are arranged above the first insulation layer, the semiconductor layer is arranged above the source and the drain, the TFT further comprises an ohm-contact layer being arranged between the semiconductor layer, the source and the drain, the ohm-contact layer comprises a second opening passing through the ohm-contact layer via a gap between the source and the drain to expose the first insulation layer, and the semiconductor layer connects to the first insulation layer via the second opening.

11. A display panel, comprising:
an array substrate and a color-film substrate arranged opposite to the array substrate, the array substrate comprises a substrate and a plurality of TFTs arranged on the substrate, the TFT comprises:
a gate;
a first insulation layer arranged above the gate;
a second insulation layer arranged above the first insulation layer;
a semiconductor layer, source, and a drain arranged between the first insulation layer and the second insulation layer; and
a conductive layer arranged above the second insulation layer, the conductive layer and the gate are electrically coupled to each other such that when the TFT is in a turn-on state, a turn-on current generated in conductive channels of the semiconductor layer is increased, and when the TFT is in a turn-off state, a turn-off current generated in the conductive channels of the semiconductor layer is decreased.

12. The display panel as claimed in claim 11, wherein a first opening is arranged above the gate, the first opening passes through the first insulation layer and the second insulation layer to expose the gate, and the conductive layer connects to the gate via the first opening.

13. The display panel as claimed in claim 11, wherein the conductive layer is an ITO film or a metallic layer.

14. The display panel as claimed in claim 11, Wherein the semiconductor layer is arranged above the first insulation layer, the source and the drain are arranged above the semiconductor layer, the TFT .further comprises an ohm-contact layer arranged between the semiconductor layer, the source and the drain, the ohm-contact layer comprises a second opening passing through the ohm-contact layer via, a. gap between the source and the drain to expose the semiconductor layer, and the second insulation layer connects to the semiconductor layer via the second opening.

15. The display panel as claimed in claim 11, wherein the source and the drain are arranged above the first insulation layer, the semiconductor layer is arranged above the source and the drain, the TFT further comprises an ohm-contact layer being arranged between the semiconductor layer, the source and the drain, the ohm-contact layer comprises a second opening passing through the ohm-contact layer via a gap between the source and the drain to expose the first insulation layer, and the semiconductor layer connects to the first insulation layer via the second opening.
